(19) United States
(12) Patent Application Publication
(10) Pub. No.: US 2008/0218560 A1
(43) Pub. Date: Sep. 11, 2008

(54) PIEZOELECTRIC ELEMENT, INK JET RECORDING HEAD AND INK JET PRINTER

(75) Inventors: Motohisa NOGUCHI, Suwa (JP); Xiaoxing WANG, Chino (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/041,897

(22) Filed: Mar. 4, 2008

(30) Foreign Application Priority Data
Mar. 5, 2007 (JP) 2007-054267

(51) Int. Cl. H01L 41/083; H01L 41/187; B41J 2/045

(52) U.S. Cl. 347/71; 310/358; 310/311

(57) ABSTRACT

A piezoelectric element includes: a first electrode formed above a base substrate; a piezoelectric layer formed above the first electrode; and a second electrode formed above the piezoelectric layer, wherein the piezoelectric layer has a plurality of voids.

The entire disclosure of Japanese Patent Application No. 2007-054267, filed Mar. 5, 2007 is expressly incorporated by reference herein.

### BACKGROUND

1. Technical Field

The present invention relates to piezoelectric elements, ink jet recording heads and ink jet printers.

2. Related Art

Piezoelectric elements that may be used in liquid jet heads have piezoelectric layers. As the method for forming the piezoelectric layers, a liquid phase method may be used. According to the liquid phase method, a piezoelectric layer is obtained through coating a piezoelectric material solution on a base substrate, and annealing the coated layer. The liquid phase method does not use a vacuum apparatus, which may be used in a CVD method or a sputter method, and therefore is advantageous from the viewpoint of the cost and environment, and the piezoelectric layer obtained has excellent characteristics. However, according to a liquid phase method, there is a problem in that large residual stress is generated in the anneal step, which leads to generation of cracks. To address such a problem, for example, Japanese Laid-open Patent Application JP-A-10-139594 describes a method including the steps of coating piezoelectric material multiple times, and annealing the coated layers all together. However, according to this method, there is a problem in that large residual stress is introduced at once, and therefore cracks would readily be generated.

### SUMMARY

In accordance with an advantage of some aspects of the invention, it is possible to provide piezoelectric elements that can alleviate residual stress to thereby control generation of cracks and has excellent piezoelectric characteristics, and ink jet recording heads and ink jet printers having such piezoelectric elements.

A piezoelectric element in accordance with an embodiment of the invention includes a first electrode formed above a base substrate, a piezoelectric layer formed above the first electrode, and a second electrode formed above the piezoelectric layer, wherein the piezoelectric layer has a plurality of voids.

According to the embodiment of the invention, because a piezoelectric layer having voids is formed, residual stress that may be generated in the piezoelectric layer can be made smaller, and therefore cracks would become difficult to occur. By this, highly reliable piezoelectric elements with good piezoelectric characteristics can be provided.

It this invention, the statement “a specific member B (hereafter referred to as a “member B”) provided above a specific member A (hereafter referred to as a “member A”) includes the case where the member B is provided directly on the member A, and the case where the member B is provided over the member A through another member provided on the member A.

In the piezoelectric element in accordance with an aspect of the embodiment, each of the voids may be 100 nm or smaller in diameter.

In the piezoelectric element in accordance with an aspect of the embodiment, the voids may be arranged in a matrix in a plane parallel with a top surface of the base substrate.

In the piezoelectric element in accordance with an aspect of the embodiment, the plurality of voids arranged in a matrix may be provided in a plurality of layers.

In the piezoelectric element in accordance with an aspect of the embodiment, the voids may be formed in a greater number per unit volume as the voids are present closer to the first electrode.

In the piezoelectric element in accordance with an aspect of the embodiment, the piezoelectric layer may have a first piezoelectric layer having a plurality of voids, and a second piezoelectric layer that is formed above the first piezoelectric layer and does not have voids.

In the piezoelectric element in accordance with an aspect of the embodiment, the piezoelectric layer may include lead zirconate titanate.

An ink jet recording head in accordance with an embodiment of the invention includes one of the piezoelectric elements described above.

An ink jet printer in accordance with an embodiment of the invention includes the ink jet recording head described above.

### BRIEF DESCRIPTION OF THE DRAWINGS

FIG. 1 is a cross-sectional view schematically showing a piezoelectric element 100 in accordance with an embodiment of the invention.

FIG. 2 is a cross-sectional view schematically showing the piezoelectric element 100 in accordance with an aspect of the embodiment of the invention.

FIG. 3 is a schematic cross-sectional view for describing a method for manufacturing a piezoelectric element 100 in accordance with an embodiment of the invention.

FIG. 4 is a schematic cross-sectional view for describing the method for manufacturing a piezoelectric element 100 in accordance with the embodiment.

FIG. 5 is a schematic cross-sectional view for describing the method for manufacturing a piezoelectric element 100 in accordance with the embodiment.

FIG. 6 is a schematic cross-sectional view for describing the method for manufacturing a piezoelectric element 100 in accordance with the embodiment.

FIG. 7 is a schematic cross-sectional view for describing the method for manufacturing a piezoelectric element 100 in accordance with the embodiment.

FIG. 8 is a cross-sectional view schematically showing a piezoelectric actuator 540 in accordance with an experimental example.

FIG. 9 is an SEM image of a cross section of a piezoelectric layer in accordance with a first experimental example.

FIG. 10 is an SEM image of a cross section of a piezoelectric layer in accordance with a second experimental example.

FIG. 11 is a cross-sectional view schematically showing a piezoelectric element 200 in accordance with a first modified example.

FIG. 12 is a cross-sectional view schematically showing a piezoelectric element 300 in accordance with a second modified example.

FIG. 13 is a cross-sectional view schematically showing a piezoelectric element 400 in accordance with a third modified example.

FIG. 14 is a cross-sectional view schematically showing a method for manufacturing the piezoelectric element 400 in accordance with the third modified example.

FIG. 15 is a cross-sectional view schematically showing a piezoelectric element 500 in accordance with a fourth modified example.

FIG. 16 is a schematic cross-sectional view of an ink jet recording head.

FIG. 17 is a schematic exploded perspective view of the ink jet recording head.

FIG. 18 is a schematic perspective view of the structure of an ink jet printer in accordance with an embodiment of the invention.

### DESCRIPTION OF EXEMPLARY EMBODIMENTS

Preferred embodiments of the invention are described below with reference to the accompanying drawings.

### 1. Piezoelectric Element

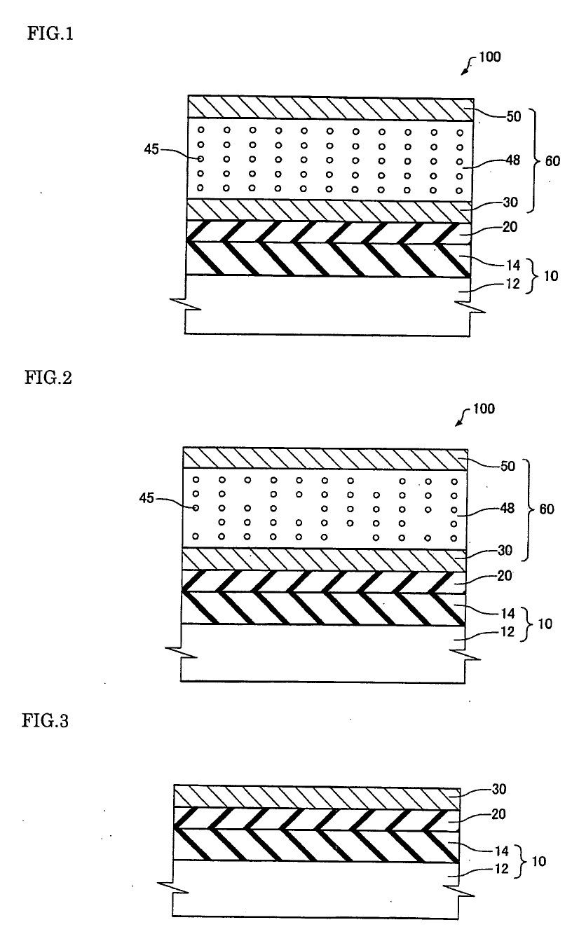

A piezoelectric element 100 in accordance with an embodiment is described. FIGS. 1 and 2 are schematic cross-sectional views of a piezoelectric element 100 in accordance with the embodiment of the invention. The piezoelectric element 100 in accordance with the present embodiment includes a substrate 10 as a part of a base substrate, an elastic layer 20, a lower electrode layer 30 (first electrode), a piezoelectric layer 48, and an upper electrode layer 50 (second electrode). The substrate 10 includes, for example, a silicon layer 12 and an oxide layer 14. The lower electrode layer 30, the piezoelectric layer 48 and the upper electrode layer 50 form a capacitor structure 60.

As the material for the lower electrode layer 30, a variety of metals such as nickel, iridium and platinum, their conductive oxides (for example, iridium oxide), and complex oxides such as SrRuO₃ and LaNiO₃ may be used. Also, the lower electrode layer 30 may have a structure with a single layer of any one of the aforementioned materials or a laminate of layers of a plurality of the materials.

As the material for the piezoelectric layer 48, an oxide including lead, zirconium and titanium as constituent elements may preferably be used. More specifically, lead zirconate titanate (hereafter referred to as PZT) is suitable as the material for the piezoelectric layer 48 for its excellent piezoelectric property.

The piezoelectric layer 48 has a plurality of voids 45. It is desirable that the diameter (the longest axis length) of each of the voids 45 is 100 nm or less. When the diameter of each of the voids 45 is greater than 100 nm, the crystal columnar structure that forms the piezoelectric layer 48 may be divided into sections in a wider range, such that the piezoelectric characteristics may deteriorate. In other words, when the diameter of each of the voids 45 is 100 nm or less, the crystal columnar structure that forms the piezoelectric layer 48 may be prevented from being divided into sections, such that the piezoelectric characteristics and the strength of the piezoelectric element 100 can be favorably maintained.

The piezoelectric layer 48 may preferably be provided with the voids 45 arranged in a matrix in a plurality of layers, as shown in FIG. 1. Moreover, the voids 45 may preferably be disposed uniformly in all of the vertical direction, the horizontal direction and the depth direction. However, it is permissible that the piezoelectric layer 48 may lack the voids in portions, for example, as shown in FIG. 2.

As the material for the upper electrode layer 50, a variety of metals such as nickel, iridium and platinum, their conductive oxides (for example, iridium oxide), and complex oxides such as SrRuO₃ and LaNiO₃ may be used. Also, the upper electrode layer 50 may be in a single layer of any one of the aforementioned materials or have a structure with a laminate of layers of a plurality of the materials.

### 2. Method for Manufacturing Piezoelectric Element

Next, a method for manufacturing a piezoelectric element 100 in accordance with an embodiment is described. FIGS. 3-7 are figures showing a method for manufacturing the piezoelectric element 100 in accordance with the present embodiment.

(1) First, a substrate 10 as a part of a base substrate is prepared (see FIG. 3). The substrate 10 has, for example, a silicon layer 12 and an oxide layer 14. The oxide layer 14 may be a layer of silicon oxide that is provided by applying an oxidation treatment to an upper portion of the silicon layer 12, or a layer of silicon oxide or other oxide that may be independently provided by a known method on the top surface of the silicon layer 12. The oxide layer 14 may be provided by a thermal oxidation treatment or the like. Alternatively, when the oxide layer 14 is independently provided on the substrate 10, a known method, such as, a vapor deposition method, a sputter method and the like may be used.

(2) Next, an elastic layer 20 is formed on the substrate 10 (see FIG. 3). The elastic layer 20 may be formed by a known method, such as, a sputter method, a vacuum deposition method, or a chemical vapor deposition method (CVD method). As the material for the elastic layer 20, for example, zirconium oxide, silicon nitride, silicon oxide or aluminum oxide may preferably be used. When the oxide layer 14 is provided on the top surface of the substrate 10, the material for the elastic layer 20 may be the same as or different from that of the oxide layer 14. For example, the elastic layer 20 may be composed of zirconium oxide, and formed by a sputter method to, for example, a thickness of 500 nm.

(3) Next, a lower electrode layer 30 (first electrode) is formed on the elastic layer 20 (see FIG. 3). The lower electrode layer 30 may be formed by a known method, such as, a sputter method, a vacuum deposition method, or a CVD method. For example, the lower electrode layer 30 may be composed of platinum, and formed by a sputter method to, for example, a thickness of 100 nm.

(4) Next, a piezoelectric layer 48 is formed on the lower electrode layer 30 (see FIG. 1). The piezoelectric layer 48 may be formed by a liquid phase method, such as, a sol-gel method, a metalorganic thermal coat decomposition method (MOD method) or the like. As the material for the piezoelectric layer 48, an oxide containing lead, zirconium and titanium as constituent elements may preferably be used. More specifically, lead zirconate titanate (hereafter referred to as PZT) is suitable as the material for the piezoelectric layer 48 for its excellent piezoelectric property. As a concrete example, the piezoelectric layer 48 may be formed as follows.

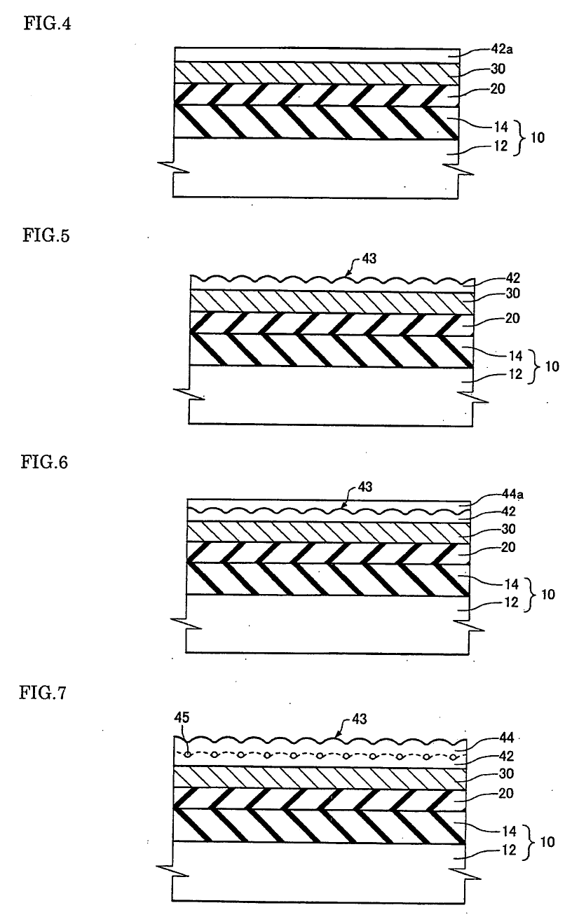

First, a piezoelectric material solution in which organometallic compounds respectively containing Pb, Zr and Ti are dissolved in a solvent is coated on the entire top surface of the lower electrode layer 30 by a spin-coat method, a dip coat method, an ink jet method or the like, thereby forming a PZT precursor layer 42a in one layer (see FIG. 4). The film thickness of the PZT precursor layer 42a may preferably be 400 nm or less, and more preferably 200 nm or less.

Next, heat treatment (drying step, cleaning step) is conducted. The drying step is conducted in order to remove the solvent, and may be conducted at about 100° C. to about 200° C. when an alcohol system solvent is used. The time duration for the drying step may be, for example, about 10 minutes. In the cleaning step, organic compositions remaining in the PZT precursor layer 42a after the drying step are thermally decomposed to NO₂, CO₂, H₂O and the like, and removed. The cleaning step may be conducted at, for example, about 300° C. to about 400° C.

Then, crystallization anneal (annealing step) for crystallizing the PZT precursor layer 42a is conducted. In the crystallization anneal, the PZT precursor layer 42a may be crystallized by heating. The crystallization anneal is conducted until multiple protrusions 43 are formed on the surface of the piezoelectric layer 42 after crystallization (see FIG. 5). The temperature for crystallization anneal is, for example, 600° C. to 700° C. Preferably, the apparatus used for crystallization anneal may be an apparatus that can heat with both radiant heat and conductive heat, and may be, for example, a diffusion furnace. By using a diffusion furnace, the protrusions 43 can be readily formed. The time duration for crystallization anneal may preferably be, for example, 30 minutes or longer. By heating for such a long time, the protrusions 43 can be more securely formed. By the steps described above, the piezoelectric layer 42 can be formed. It is noted that the apparatus used for crystallization anneal is not limited to the one described above, and other apparatuses such as a RTA (rapid thermal annealing) apparatus may be used.

Then, a piezoelectric material solution is coated on the piezoelectric layer 42, whereby a PZT precursor layer 44a in one layer is formed (see FIG. 6). The coating method, material and film thickness for forming the PZT precursor layer 42a described above may similarly be used in forming the PZT precursor layer 44a.

Then, after conducting heat treatment (drying step, cleaning step), crystallization anneal (annealing step) for crystallizing the PZT precursor layer 44a is conducted (see FIG. 7). The conditions for the heat treatment described above may similarly be applied in this heat treatment step. Protrusions 43 are also formed on the surface of the piezoelectric layer 44.

After the protrusions 43 are formed in this manner, the steps of coating a piezoelectric material solution, drying and cleaning, and the crystallization anneal step are conducted, whereby voids 45 are formed between the piezoelectric layer 42 and the piezoelectric layer 44. The voids 45 are generally formed between adjacent ones of the protrusions 43. The voids 45 are arranged in a matrix form in a plane parallel with the top surface of the substrate 10 between the piezoelectric layer 42 and the piezoelectric layer 44.

Furthermore, the steps of coating a piezoelectric material solution, drying and cleaning, and the crystallization anneal step are repeated, whereby a piezoelectric layer 48 in a thick film can be formed (see FIG. 1 and FIG. 2). It is noted that protrusions may not be formed on the topmost surface of the piezoelectric layer 48. Accordingly, the crystallization anneal for the PZT precursor layer at the topmost layer composing the piezoelectric layer 48 can be completed in a shorter time than the crystallization anneal for the lower layers. By this, the top surface of the piezoelectric layer 48 becomes flat, which can improve the adhesion with an upper electrode layer 50 to be described below. Also, when the invention is applied to a plurality of substrates, the following method may be used such that the piezoelectric layer 48 can be formed with a stabilized perovskite structure, and the throughput can be improved. First, coating and heat treatment are conducted for a lower piezoelectric layer. Then, a RTA apparatus, which is a sheet-after-sheet type apparatus, is used to apply the crystallization step to the lower piezoelectric layer. By crystallizing the layer with RTA, a piezoelectric layer having a more stable perovskite structure can be formed, compared to the case where a diffusion furnace is used. Then, coating and heat treatment are applied to these substrates for forming a piezoelectric layer in an upper layer. Then, crystallization anneal is conducted to the plurality of substrates in a diffusion furnace that is capable of batch processing. This can improve the throughput, compared to the case where a sheet-after-sheet type RTA apparatus is used. Moreover, as the piezoelectric layer in the lower layer has a stable perovskite structure due to the RTA treatment, the piezoelectric layer in the upper layer succeeds the crystal structure of the lower layer, and thus has a stable perovskite structure even when the upper layer is thermally treated in the diffusion furnace. It may be sufficient if the steps of coating the piezoelectric material solution, drying and cleaning and the crystallization annealing step are repeated at least two times.

(5) Next, an upper electrode layer 50 (second electrode) is formed on the piezoelectric layer 48. The upper electrode layer 50 may be formed by a known method, such as, a sputter method, a vacuum deposition method, or a CVD method. For example, the upper electrode layer 50 may be composed of platinum, and formed by a sputter method to, for example, a thickness of 100 nm. By the steps described above, a capacitor structure section 60 composed of the lower electrode layer 30, the piezoelectric layer 48 and the upper electrode layer 50.

By the steps described above, a piezoelectric element 100 in accordance with the present embodiment is fabricated. According to the method for manufacturing the piezoelectric element 100 in accordance with the present embodiment, when forming the piezoelectric layer 48, crystallization anneal is conducted each time the piezoelectric material solution is coated. By this, the voids 45 can be formed in the piezoelectric layer 48, whereby residual stress can be alleviated, and generation of cracks can be suppressed. Further, by controlling the diameter of each of the voids 45 to be 100 nm or less, the crystal columnar structure that forms the piezoelectric layer 48 can be prevented from being divided into sections, such that the piezoelectric characteristics and the strength of the piezoelectric element 100 can be favorably maintained. Furthermore, the voids 45 may preferably be arranged uniformly in all of the vertical, horizontal and depth directions in FIG. 1. By this, stress can be uniformly alleviated throughout the piezoelectric layer 48, and generation of cracks can be more reliably suppressed. The distance between the voids 45 in the vertical direction depends on the film thickness of the coated PZT precursor layer 42a. When the film thickness of the PZT precursor layer 42a is set to 400 nm or less, the voids 45 can be densely arranged, and the residual stress can be greatly alleviated. Also, by setting the film thickness of the PZT precursor layer 42a to 200 nm or less, the residual stress can be further substantially alleviated.

### 3. Experimental Example

As experimental examples, piezoelectric actuators 540, each of which includes the piezoelectric element 100, were fabricated. The piezoelectric actuators 540 were pulse-driven and the state of crack generation was observed.

### 3.1. First Experimental Example

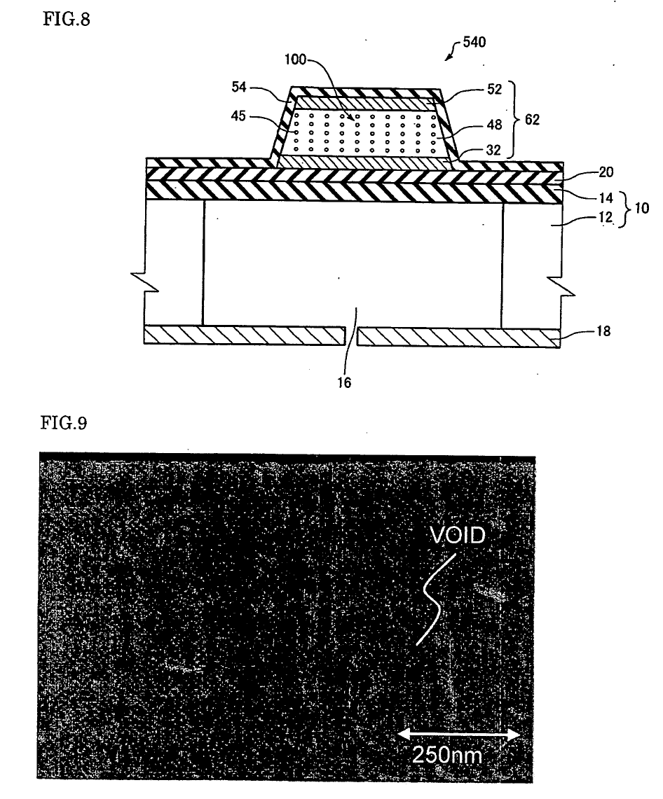

According to a first experimental example, a piezoelectric actuator 540 using a piezoelectric element was manufactured by using the method for manufacturing a piezoelectric element in accordance with the embodiment described above. FIG. 8 is a schematic cross-sectional view of the piezoelectric actuator fabricated in the first experimental example.

The piezoelectric actuator 540 includes a substrate 10, a pressure generation chamber 16 provided in the substrate 10, an elastic layer provided above the substrate 10, and a capacitor structure section 62 provided above the elastic layer 20, wherein the capacitor structure section 62 has a lower electrode layer 32, a piezoelectric layer 47 and an upper electrode layer 52.

The substrate 10 functions as a supporting body for the piezoelectric actuator 540 in accordance with the present embodiment. Below the substrate 10, there are provided the pressure generation chamber 16 and a nozzle plate 18 provided below the pressure generation chamber 16.

The piezoelectric actuator 540 was manufactured as follows.

First, a silicon substrate 12 was prepared, and its top surface was oxidized to form a silicon oxide layer 14 of about 1.0 μm in thickness. Then, an elastic layer 20 composed of zirconium oxide having a thickness of about 500 nm, and a lower electrode layer 32 composed of platinum having a thickness of 100 nm on the elastic layer 20 were formed by a sputter method.

Then PZT solution was coated on the lower electrode layer 32 by a spin coat method, dried, cleaned and sintered, thereby crystallizing the coated layer. The sintering step was conducted in a diffusion furnace for 30 minutes. The film thickness after crystallization was 200 nm, and the coating, drying, cleaning and sintering steps were repeated five times, whereby a PZT layer 47 having a film thickness of 1 μm was obtained. FIG. 9 shows a SEM (scanning electron microscope) image of a cross section of the PZT layer 47. It was confirmed from the SEM image that voids are present.

Then, an upper electrode layer 52 composed of platinum with a thickness of 100 nm was formed, and a protection film 54 composed of aluminum oxide and wirings (not shown) were formed by patterning. Furthermore, the silicon substrate 12 was etched from its bottom side whereby a pressure generation chamber 16 was formed, and was equipped with a nozzle plate 18.

The piezoelectric actuator 540 obtained was pulse-driven, and no crack was generated even when it was pulse-driven 10 billion times. Also, the piezoelectric characteristic of the piezoelectric actuator 540 was evaluated, which was d31=200 (pC/N).

### 3.2. Second Experimental Example

According to a second experimental example, a piezoelectric actuator was manufactured as follows. The structure of the piezoelectric actuator according to the second experimental example was generally the same as the structure of the piezoelectric actuator 540 in accordance with the first experimental example described above.

The piezoelectric actuator was manufactured as follows.

First, a silicon substrate 12 was prepared, and its top surface was oxidized to form a silicon oxide layer 14 of about 1.0 μm in thickness. Then, an elastic layer 20 composed of zirconium oxide having a thickness of about 500 nm, and a lower electrode layer 32 composed of platinum having a thickness of 100 nm on the elastic layer 20 were formed by a sputter method.

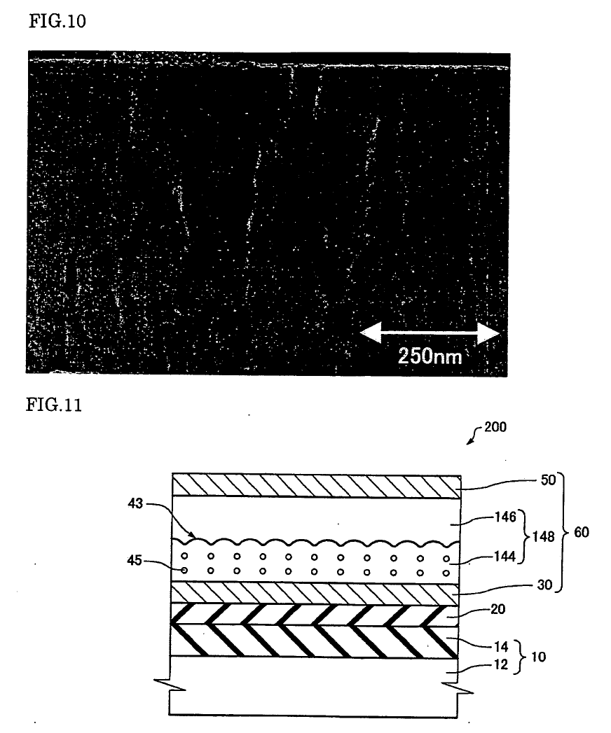

Then PZT solution was coated on the lower electrode layer 32 by a spin coat method, dried, cleaned and sintered, thereby crystallizing the coated layer. The sintering step was conducted with RTA for 5 minutes. The film thickness after crystallization was 200 nm, and the coating, drying, cleaning and sintering steps were repeated five times, whereby a PZT layer 47 having a film thickness of 1 μm was obtained. FIG. 10 shows a SEM (scanning electron microscope) image of a cross section of the PZT layer 47. No void was recognized in the SEM image.

Then, an upper electrode layer 52 composed of platinum with a thickness of 100 nm was formed, and a protection film 54 composed of aluminum oxide and wirings (not shown) were formed by patterning. Furthermore, the silicon substrate 12 was etched from its bottom side whereby a pressure generation chamber 16 was formed, and then was equipped with a nozzle plate 18.

The piezoelectric actuator obtained was pulse-driven, and cracks were generated when it was pulse-driven 1 billion times. Also, the piezoelectric characteristic of the piezoelectric actuator was evaluated, which was d31=150 (pC/N).

### 3.3. Third Experimental Example

According to a third experimental example, a piezoelectric actuator was manufactured as follows. The structure of the piezoelectric actuator according to the third experimental example was generally the same as the structure of the piezoelectric actuator 540 in accordance with the first experimental example described above.

The piezoelectric actuator was manufactured as follows.

First, a silicon substrate 12 was prepared, and its top surface was oxidized to form a silicon oxide layer 14 of about 1.0 μm in thickness. Then, an elastic layer 20 composed of zirconium oxide having a thickness of about 500 nm, and a lower electrode layer 32 composed of platinum having a thickness of 100 nm on the elastic layer 20 were formed by a sputter method.

Then PZT solution was coated on the lower electrode layer 32 by a spin coat method, dried, and cleaned for crystallization. The steps of coating, drying and cleaning were repeated five times, and then the layers were sintered all together. The sintering step was conducted with RTA for 10 minutes, whereby a PZT layer having a film thickness of 1 μm was obtained.

Then, an upper electrode layer 52 composed of platinum with a thickness of 100 nm was formed, and a protection film composed of aluminum oxide and wirings (not shown) were formed by patterning. Furthermore, the silicon substrate 12 was etched from its bottom side whereby a pressure generation chamber 16 was formed, and then was equipped with a nozzle plate 18.

The piezoelectric actuator 540 obtained was pulse-driven. Cracks were generated when it was pulse-driven 1 billion times. Also, the piezoelectric characteristic of the piezoelectric actuator was evaluated, which was d31=100 (pC/N).

According to the first to third experimental examples, it was confirmed that cracks became difficult to occur when the sintering step was conducted for each of the PZT precursor layers, compared to the case where the sintering step was conducted for all of the layers at once. Also, voids were created when heating in the sintering step was conducted with a diffusion furnace for 30 minutes or longer, and it was confirmed that cracks became more difficult to occur in this case. Moreover, it was also confirmed that the piezoelectric characteristic was improved due to the formation of voids.

### 4. Modified Example

Modified examples in accordance with the present embodiment are described next.

### 4.1. First Modified Example

A piezoelectric element in accordance with a first modified example has voids only in a lower layer of a piezoelectric layer, and is therefore different from the piezoelectric layer 100 that has voids provided throughout the entire piezoelectric layer 48.

FIG. 11 is a schematic cross-sectional view of a piezoelectric element 200 in accordance with the first modified example. More specifically, its structure and manufacturing method are as follows.

The piezoelectric element 200 in accordance with the first modified example includes a substrate 10 as a part of a base substrate, an elastic layer 20, a lower electrode layer 30 (first electrode), a piezoelectric layer 148, and an upper electrode layer 50 (second electrode). The piezoelectric layer 148 has a first piezoelectric layer 144 formed on the lower electrode 30, and a second piezoelectric layer 146 formed on the first piezoelectric layer 144. The first piezoelectric layer 144 has voids, and the second piezoelectric layer 146 does not have voids. Protrusions 43 may or may not be formed at the interface between the first piezoelectric layer 144 and the second piezoelectric layer 146.

Next, a method for manufacturing the piezoelectric element in accordance with the first modified example is described.

First, according to the steps (1) to (4) of the method for manufacturing a piezoelectric element in accordance with the embodiment described above, a substrate 10, an elastic layer 20, a lower electrode 30 and a first piezoelectric layer 144 (corresponding to the piezoelectric layer 48) are formed.

Next, piezoelectric material solution is coated on the first piezoelectric layer 144, and heat treatment (drying step, cleaning step) is conducted. Only the steps of coating piezoelectric material solution, drying and cleaning are repeated. By these steps, PZT precursor layers in a plurality of layers are formed. Then, the plurality of PZT precursor layers are annealed for crystallization all at once, whereby a second piezoelectric layer 146 can be formed on the first piezoelectric layer 144.

Then, an upper electrode layer 50 (second electrode) is formed on the second piezoelectric layer 146. The step to be conducted hereafter is generally the same as the step (5) described above, and therefore its description is omitted.

By the steps described above, the piezoelectric element 200 in accordance with the modified example is manufactured. The piezoelectric layer 148 of the piezoelectric element 200 has the first piezoelectric layer 144 and the second piezoelectric layer 146, wherein only the lower layer, namely, the first piezoelectric layer 144, has the voids 45. When a piezoelectric layer is formed by a liquid phase method, residual stress would concentrate on the side of the lower electrode layer 30 due to a difference in the thermal expansion coefficient; and upon driving the piezoelectric element, greater distortion stress is concentrated at the interface between the lower electrode that does not warp and the piezoelectric layer that warps. Accordingly, by forming the voids 45 only in the lower layer, which is the first piezoelectric layer 144, as in the present modified example, residual stress and distortion stress are effectively alleviated; and by annealing the layers at once at the upper layer, the throughput can be improved.

### 4.2. Second Modified Example

A piezoelectric element in accordance with a second modified example has voids only in a lower layer of a piezoelectric layer and the arrangement of the voids is not in a matrix, and is therefore different from the piezoelectric layer 100 in accordance with the embodiment described above.

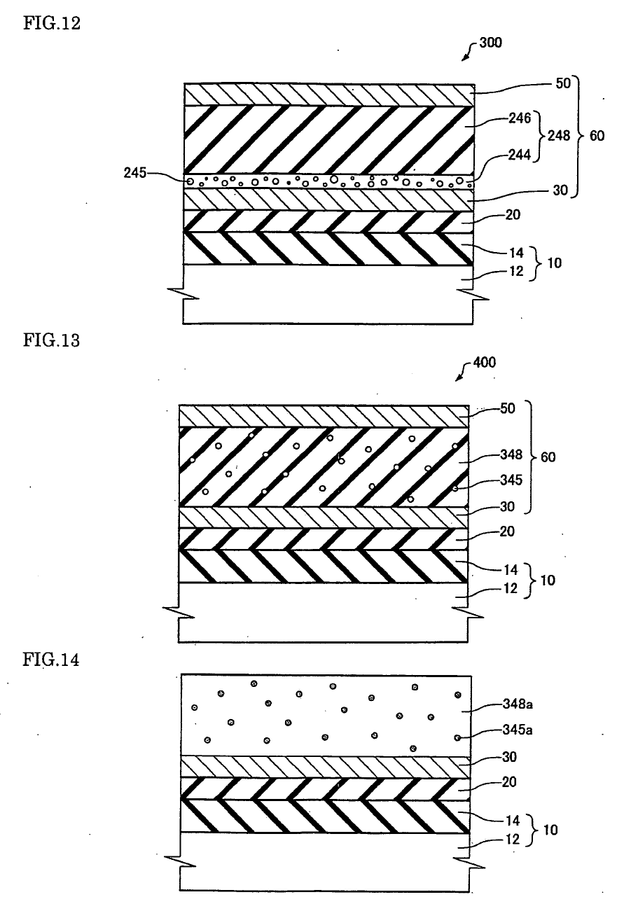

FIG. 12 is a schematic cross-sectional view of a piezoelectric element 300 in accordance with the second modified example. More specifically, its structure and manufacturing method are as follows.

The piezoelectric element 300 in accordance with the second modified example includes a substrate 10 as a part of a base substrate, an elastic layer 20, a lower electrode layer 30 (first electrode), a piezoelectric layer 248, and an upper electrode layer 50 (second electrode). The piezoelectric layer 248 has a first piezoelectric layer 244 formed on the lower electrode 30, and a second piezoelectric layer 246 formed on the first piezoelectric layer 244. The first piezoelectric layer 244 has voids, and the second piezoelectric layer 246 does not have voids. The first piezoelectric layer 244 has a plurality of voids 245.

Next, a method for manufacturing the piezoelectric element in accordance with the second modified example is described.

First, according to the steps (1) to (3) of the method for manufacturing a piezoelectric element in accordance with the embodiment described above, a substrate 10, an elastic layer 20, and a lower electrode 30 are formed.

Then, a first piezoelectric layer 244 and a second piezoelectric layer 246 are formed on the lower electrode layer 30 (see FIG. 12). As the material for the first piezoelectric layer 244 and the second piezoelectric layer 246, an oxide including lead, zirconium and titanium as constituent elements may preferably be used. More specifically, lead zirconate titanate (hereafter referred to as PZT) is suitable as the material for the first piezoelectric layer 244 and the second piezoelectric layer 246 for its excellent piezoelectric property. Concretely, the first piezoelectric layer 244 and the second piezoelectric layer 246 are formed as described below. Also, the first piezoelectric layer 244 formed as a lower layer among the first piezoelectric layer 244 and the second piezoelectric layer 246 has voids. The size and number of the voids may differ according to the magnitude of the stress to be generated between the lower electrode layer 30 and the second piezoelectric layer 246.

By placing the first piezoelectric layer 244 having the voids between the lower electrode layer 30 and the second piezoelectric layer 246, the residual stress can be alleviated, and generation of cracks can be suppressed.

The first piezoelectric layer 244 and the second piezoelectric layer 246 may be formed by a liquid phase method, such as, a sol-gel method, a metalorganic thermal coat decomposition method (MOD method) or the like. More specifically, they are formed as follows.

First, piezoelectric material solution and polymer solution are mixed to prepare polymer containing piezoelectric material solution. As the piezoelectric material solution, known piezoelectric material solutions may be used. For example, a piezoelectric material solution in which organometallic compounds respectively containing Pb, Zr and Ti are dissolved in a solvent may be used. As the polymer solution, a polymer solution in which polymer, such as, for example, polyacrylic acid (PAA), polyvinylpyrrolidone (PVP), polyethylene glycol (PEG), or polyvinyl alcohol (PVA) is dissolved in a solvent such as ethanol can be used.

In accordance with the present embodiment, for example, when PVP is used as the polymer, its molecular weight may preferably be 300,000 to 1,500,000, and the amount of added polymer in the polymer containing piezoelectric material solution may preferably be 0.5 wt % to 10 wt %.

By adjusting the molecular weight and adding amount of the polymer to be dissolved in the polymer solution, the size and the number of voids can be adjusted according to the magnitude of stress to be generated. In other words, based on the desired size and number of the voids, the molecular weight and adding amount of the polymer to be dissolved in the polymer solution can be decided. The magnitude of stress may be determined by the film thickness of the first piezoelectric layer 244, the film thickness ratio between the first piezoelectric layer 244 and the second piezoelectric layer 246, the kinds of the piezoelectric material and solvent, the electrode material and the like. Therefore, the amount of polymer to be added may preferably be decided based on the film thickness of the first piezoelectric layer 244, the film thickness ratio between the first piezoelectric layer 244 and the second piezoelectric layer 246, the kinds of the piezoelectric material and solvent, the electrode material and the like. The amount of polymer to be added may be made smaller as the film thickness rate of the first piezoelectric layer 244 becomes greater in the film thickness ratio between the first piezoelectric layer 244 and the second piezoelectric layer 246. By this, it is possible to obtain a polymer concentration according to the stress that is generated in both of the first piezoelectric layer 244 and the second piezoelectric layer 246.

Then, the polymer containing piezoelectric material solution is coated on the entire top surface of the lower electrode layer 30 by a spin coat method, a dip coat method, or an ink jet method, thereby forming a single precursor layer or a plurality of precursor layers (not shown).

Next, heat treatment (drying step, cleaning step) is conducted. The temperature of the drying step may preferably be, for example, between 150° C. and 200 ° C., and more preferably about 180° C. The time duration for the drying step may be, for example, five minutes or longer, and preferably about 10 minutes. In the cleaning step, organic compositions remaining in the precursor layer 42a after the drying step are thermally decomposed into NO₂, CO₂, H₂O and the like, and removed. The temperature for the cleaning step may be, for example, about 300° C.

Then, crystallization anneal (annealing step) for crystallizing the precursor layer is conducted. In the crystallization anneal, the precursor layer may be crystallized by heating. The temperature for crystallization anneal is, for example, 600° C. to 700° C. The apparatus used for crystallization anneal may be, for example, a diffusion furnace or a RTA (rapid thermal annealing) apparatus. The time duration for crystallization anneal is, for example, between 5 minutes and 30 minutes. By the crystallization anneal, the polymer described above is gasified, whereby a plurality of voids are generally uniformly formed throughout the entire first piezoelectric layer 244. In this manner, the first piezoelectric layer 244 is formed.

The film thickness of the first piezoelectric layer 244 may preferably be about 50 nm to about 150 nm. When the film thickness is set to be 50 nm or greater, stress can be sufficiently alleviated; and when the film thickness is set to be 150 nm or less, the piezoelectric characteristic of the piezoelectric element can be favorably maintained.

Then, a second piezoelectric layer 246 is formed on the first piezoelectric layer 244. The piezoelectric material solution described above is coated on the first piezoelectric layer 244, and heat treatment (drying step, cleaning step) is conducted. The steps of coating, drying and cleaning are repeated several times, and thereafter, the formed plural layers are sintered all together, whereby the second piezoelectric layer 246 is formed. It is noted that the details of the coating method, drying step and cleaning step for forming the second piezoelectric layer 246 are generally the same as those used in forming the first piezoelectric layer 244. Also, the piezoelectric material contained in the second piezoelectric layer 246 may preferably be the same as the piezoelectric material contained in the first piezoelectric layer 244. By this, the second piezoelectric layer 246 in a favorable crystal state can be obtained.

The film thickness of the second piezoelectric layer 246 may be greater than that of the first piezoelectric layer 244, and may be, for example, about 800 nm to about 1000 nm. The second piezoelectric layer 246 uses the polymer described above in its forming process, and thus does not have voids. By providing the second piezoelectric layer 246 with such a property, the favorable piezoelectric characteristic can be maintained.

Then, an upper electrode layer 50 (second electrode) is formed on the second piezoelectric layer 246. The upper electrode layer 50 may be formed generally in the same manner as described above in the first embodiment, and therefore its description is omitted.

By the steps described above, the piezoelectric element 300 in accordance with the present embodiment is fabricated. According to the method for forming the piezoelectric element 300 in accordance with the second modified example, the first piezoelectric layer 244 having voids is formed on the lower electrode layer 30, residual stress generated on the first piezoelectric layer 244 and the second piezoelectric layer 246 can be alleviated, whereby generation of cracks can be suppressed. Also, by alleviating the residual stress in this manner, the amount of piezoelectric displacement of the piezoelectric element 100 can be improved.

Furthermore, by providing the second piezoelectric layer 246 that does not have voids, the piezoelectric characteristic can be favorably maintained. Moreover, in accordance with the method for forming the piezoelectric element 100 in accordance with the present embodiment, by adjusting the molecular weight of polymer and the amount of the polymer to be added for forming the first piezoelectric layer 244, the size and number of voids can be controlled, and voids in suitable size and number can be readily formed according to the kind of the piezoelectric material and the film thickness of each of the layers.

### 4.3. Third Modified Example

### 4.3.1. Piezoelectric Element, and its Manufacturing Method

A piezoelectric element in accordance with a third modified example has voids that are not in a matrix, which is different from the piezoelectric element 100 in accordance with the present embodiment.

FIG. 13 is a schematic cross-sectional view of a piezoelectric element 400 in accordance with the third modified example. Details of the structure and manufacturing method are as follows.

The piezoelectric element 400 in accordance with the third modified example includes a substrate 10 as a part of a base substrate, an elastic layer 20, a lower electrode layer 30 (first electrode), a piezoelectric layer 348, and an upper electrode layer 50 (second electrode). The piezoelectric layer 348 includes a plurality of voids. The plurality of voids 345 may have generally the same diameter and shape.

Next, a method for manufacturing a piezoelectric element in accordance with the third modified example is described. FIG. 14 is a cross-sectional view showing the method for manufacturing a piezoelectric element in accordance with the third modified example.

First, according to the steps (1) to (3) of the method for manufacturing a piezoelectric element in accordance with the embodiment described above, a substrate 10, an elastic layer 20, and a lower electrode 30 are formed.

Next, a piezoelectric layer 348 is formed on the lower electrode layer 30. The piezoelectric layer 348 may be formed by a liquid phase method, such as, a sol-gel method, a metalorganic thermal coat decomposition method (MOD method) or the like. As the material for the piezoelectric layer 348, an oxide including lead, zirconium and titanium as constituent elements may preferably be used. More specifically, lead zirconate titanate (hereafter referred to as PZT) is suitable as the material for the piezoelectric layer 348 for its excellent piezoelectric property. Concretely, the piezoelectric layer 348 is formed as described below.

First, a method for preparing piezoelectric material solution of lead zirconate titanate is described, using, as an example, the case where a sol-gel method is to be employed. First, organometallic compounds of Pb, Zr and Ti are prepared, and mixed in a solvent. As the solvent, alcohols, such as, for example, ethanol, 1-buthanol, and 2-n-butoxyethanol may be used. Then, water is further added to the solution to cause hydrolysis and polycondensation, thereby preparing precursor solution (piezoelectric material solution).

Then, plural solid polymers are mixed in the precursor solution to prepare solid polymer containing piezoelectric material solution. The solid polymers may preferably be non-soluble or have a low solubility in the major solvent of the precursor solution. In other words, it is desirable that the solid polymers can stably disperse in the precursor solution. The particle shape of the solid polymers may be generally globular, generally hexahedron or the like, without any particular limitation, and its diameter (the longest major axis) may preferably be 200 nm or less, and more preferably 100 nm or less. The melting point of the solid polymers may preferably be higher than the temperature at which drying step and cleaning step to be described below are conducted. In other words, the melting point of the solid polymers may preferably be higher than the boiling point of the solvent of the precursor solution, for example, 400° C. or higher. As the materials for the solid polymers, for example, heat-resistant resins may be used, which may preferably have a higher melting point than the temperature of the drying step and the cleaning step to be described below, and decompose (gasify) at the temperature of crystallization anneal. More specifically, fluororesin, polycarbonate resin, and polyimide resin may be used.

Then, the prepared solid polymer piezoelectric material solution is coated on the entire top surface of the lower electrode layer 30 by a spin coat method, a dip coat method, an ink jet method or the like.

Next, heat treatment (drying step, cleaning step) is conducted. The drying step is conducted in order to remove the solvent, and may be conducted at about 100° C. to about 200° C. when an alcohol system solvent is used. The time duration for the drying step may be, for example, about 10 minutes. In the cleaning step, organic compositions remaining in the PZT precursor layer 348a after the drying step are thermally decomposed into NO₂, CO₂, H₂O and the like, and removed. The cleaning step may be conducted at, for example, about 300° C. to about 400° C. The coating step and the heat treatment (drying step, cleaning step) are repeated until the coated film reaches a desired film thickness, thereby forming a PZT precursor layer 348a (see FIG. 14). The PZT precursor layer 348a contains a plurality of solid polymers 345a.

Then, crystallization anneal (annealing step) for crystallizing the PZT precursor layer 348a is conducted. In the crystallization anneal, the PZT precursor layer 348a can be crystallized by heating, and the solid polymers 345a can be vaporized.

The temperature for crystallization anneal is, for example, 600° C. to 700° C. As the apparatus used for crystallization anneal, for example, a diffusion furnace and a RTA (rapid thermal annealing) apparatus may be used. By the steps described above, a piezoelectric layer 348 having the multiple voids 345 can be formed. The piezoelectric layer 348 may be formed, for example, in a thickness of 400 nm.

Then, an upper electrode layer 50 (second electrode) is formed on the piezoelectric layer 348. The upper electrode layer 50 may be formed generally in the same manner as described above in the first embodiment, and therefore its description is omitted.

By the steps described above, the piezoelectric element 400 in accordance with the third modified example is formed. According to the method for manufacturing the piezoelectric element 400 in accordance with the third modified example, solid polymers are mixed in the precursor solution. As a result, when the PZT precursor layer 348a is annealed for crystallization, the solid polymers 345a gasify, such that the voids 345 can be provided in the piezoelectric layer 348. By this, the voids 345 can be formed in the piezoelectric layer 348, whereby the residual stress can be alleviated, and generation of cracks can be suppressed.

Moreover, in accordance with the third modified example, the solid polymers 345a that are formed materials are used for creating the voids 345. Therefore, the voids 345 in suitable size and number can be readily provided by adjusting the size and number of the solid polymers 345a. Accordingly, the size and number of the voids 345 can be readily changed according to the material and film thickness of the piezoelectric layer 348, and the material and film thickness of the lower electrode layer 30.

Also, as described above, the diameter of each of the voids 345 may preferably be 100 nm or less. The voids 345 in this size can be readily formed, by using the method for manufacturing a piezoelectric element in accordance with the third modified example.

Also, the solid polymers may preferably be non-soluble or have a low solubility in the solvent of the precursor solution, and may preferably have a melting point higher than the temperature at which the drying step and the cleaning step are conducted. By this, the shape of the solid polymers can be maintained until they are decomposed (gasified) at the time of crystallization anneal, such that the shape of the voids can be readily adjusted. Furthermore, the solid polymers do not mix with the piezoelectric material solution, such that the characteristics of the piezoelectric layer 348 can be prevented from being affected by the solid polymers. If polymers that can readily dissolve in the piezoelectric material solution were used, the drying, cleaning and crystallization anneal steps to be conducted later would not smoothly proceed, such that the piezoelectric characteristics of the piezoelectric layer to be obtained would be considerably deteriorated.

### 4.3.2. Experimental Example

By using the method for manufacturing a piezoelectric element in accordance with the third modified example described above, a piezoelectric actuator 540 using the piezoelectric element was fabricated. (FIG. 8)

The piezoelectric actuator 540 includes a substrate 10, a pressure generation chamber 16 provided in the substrate 10, an elastic layer 20 provided above the substrate 10, an a capacitor structure 62 provided above the elastic layer 20, wherein the capacitor structure 62 includes a lower electrode layer 32, a piezoelectric layer 48 and an upper electrode layer 52.

The substrate 10 functions as a supporting body for the piezoelectric actuator 540 in accordance with the present embodiment. Below the substrate 10, there are provided the pressure generation chamber 16 and a nozzle plate 18 provided below the pressure generation chamber 16.

The piezoelectric actuator 540 was manufactured as follows.

First, a silicon substrate 12 was prepared, and its top surface was oxidized to form a silicon oxide layer 14 of about 1.0 μm in thickness. Then, an elastic layer 20 composed of zirconium oxide having a thickness of about 500 nm, and a lower electrode layer 32 composed of platinum having a thickness of about 100 nm on the elastic layer 20 were formed by a sputter method.

Then, PZT solution containing polymer beads dispersed therein was coated on the lower electrode layer 32 by a spin coat method, dried, cleaned and sintered, thereby crystallizing the coated layer. The sintering step was conducted with RTA for 5 minutes. The film thickness after crystallization was 200 nm, and the coating, drying, cleaning and sintering steps were repeated five times, whereby a PZT layer 48 having a film thickness of 1 μm was obtained. It was confirmed from a SEM image that voids were formed in the obtained PZT layer 48 due to the decomposition and gasification of the polymer beads.

Then, an upper electrode layer 52 composed of platinum with a thickness of 100 nm was formed, and a protection film 54 composed of aluminum oxide and wirings (not shown) were formed by patterning. Furthermore, the silicon substrate 12 was etched from its bottom side whereby a pressure generation chamber 16 was formed, and was equipped with a nozzle plate 18.

The piezoelectric actuator 540 obtained was pulse-driven. No crack was generated even when it was pulse-driven 10 billion times. Also, the piezoelectric characteristic of the piezoelectric actuator 540 evaluated was d31=200 (pC/N).

In this manner, it was confirmed that, by forming the piezoelectric layer with polymer beads, the piezoelectric characteristic was improved, and cracks become difficult to be generated.

### 4.4. Fourth Modified Example

According to a piezoelectric layer in accordance with the fourth modified example, voids are arranged not in a matrix, and the voids are more densely arranged as the voids are located closer to the lower electrode layer side.

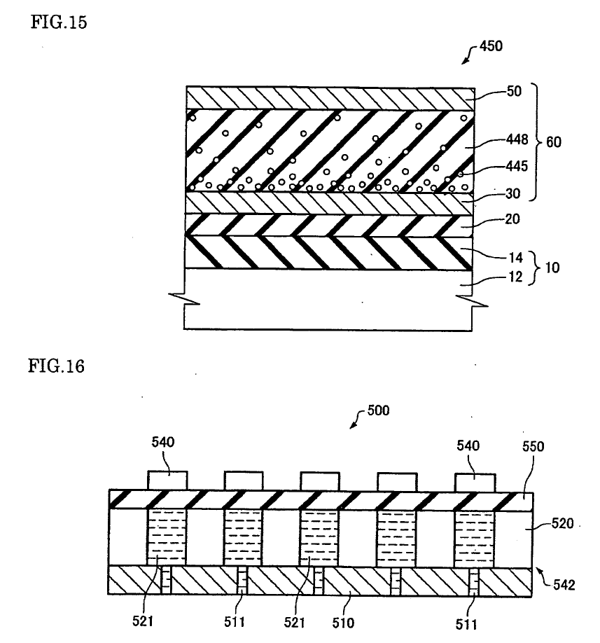

FIG. 15 is a schematic cross-sectional view of a piezoelectric element 450 in accordance with the fourth modified example. More specifically, its structure and manufacturing method are as follows.

The piezoelectric element 450 in accordance with the fourth modified example includes a substrate 10 as a part of a base substrate, an elastic layer 20, a lower electrode layer 30 (first electrode), a piezoelectric layer 448, and an upper electrode layer 50 (second electrode). The piezoelectric layer 448 includes a plurality of voids 445. The plurality of voids 445 may have generally the same diameter and shape.

The method for manufacturing a piezoelectric element in accordance with the fourth modified example may be generally the same as the method for manufacturing a piezoelectric element in accordance with the third modified example, but, for example, suitable solid polymer containing solution needs to be prepared in order to provide the voids 445 in a greater number per unit volume as the voids 445 are present closer to the lower electrode side (lower side). A variety of methods may be possible to achieve this object. For example, to achieve the object, solid polymers 345a having a higher density than that of the piezoelectric material solution may be selected. Alternatively, a piezoelectric layer may be formed initially with solid polymer containing solution containing the solid polymers 345a, and then another piezoelectric layer may be formed with piezoelectric material solution that does not contain the solid polymers 345a.

### 5. Ink Jet Recording Head

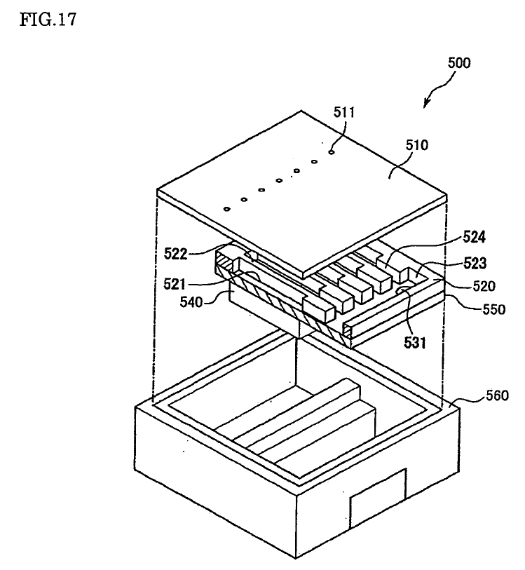

Next, an ink jet recording head using the piezoelectric element 100 shown in FIG. 1 is described. FIG. 16 is a side cross-sectional view schematically showing the structure of an ink jet recording head using the piezoelectric element 100 shown in FIG. 1. FIG. 17 is an exploded perspective view of the ink jet recording head. It is noted that FIG. 17 shows the head upside down with respect to a state in which it is normally used.

The ink jet recording head (hereafter also referred to as the “head”) 500 is equipped with a head main body 542 and piezoelectric sections 540 provided above the head main body 542, as shown in FIG. 16. It is noted that each of the piezoelectric sections 540 shown in FIG. 16 corresponds to the piezoelectric element 100 shown in FIG. 1, which has the lower electrode layer 30, the piezoelectric layer 48, and the upper electrode layer 50. Also, in the ink jet recording head in accordance with the present embodiment, the piezoelectric element 100 can function as a piezoelectric actuator. The piezoelectric actuator is an element having a function to move substance, in other words, an element that generates mechanical strain upon application of a voltage.

Also, the oxide layer 14 and the elastic layer 20 in the piezoelectric element 100 shown in FIG. 1 correspond to an elastic film 550 in FIG. 16. The substrate 10 forms a main portion of a head main body 542 to be described below (see FIG. 16).

More specifically, the head 500 is equipped with a nozzle plate 510, an ink chamber substrate 520, an elastic film 550, and piezoelectric sections (vibration sources) 540 that are bonded to the elastic plate 550, which are housed in a base substrate 560, as shown in FIG. 17. The head 500 forms an on-demand type piezoelectric jet head.

The nozzle plate 510 is formed from, for example, a rolled plate of stainless steel or the like, and includes multiple nozzles 511 formed in a row for jetting ink droplets. The pitch of the nozzles 511 may be appropriately set according to the printing resolution.

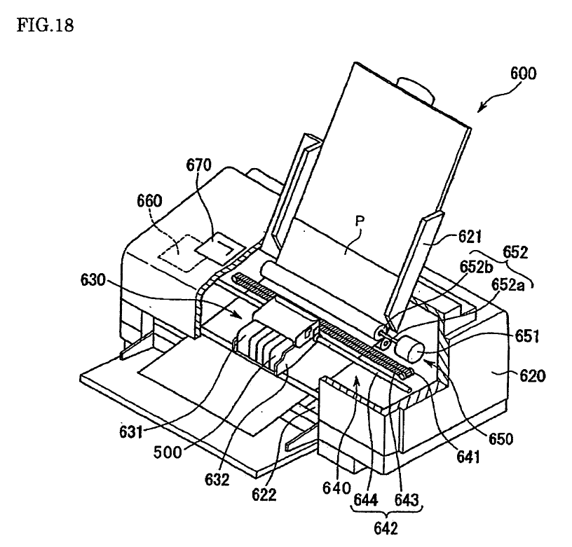

The ink chamber substrate 520 is fixedly bonded (affixed) to the nozzle plate 510. The ink chamber substrate 520 is formed with the silicon substrate 12 described above. The ink chamber substrate 520 has a plurality of cavities (ink cavities) 521, a reservoir 523, and supply ports 524, which are defined by the nozzle plate 510, side walls (partition walls) 522 and the elastic film 550 to be described below. The reservoir 523 temporarily reserves ink that is supplied from an ink cartridge 631 (see FIG. 18). The ink is supplied from the reservoir 523 to the respective cavities 521 through the supply ports 524.

The cavity 521 is disposed for each of the corresponding nozzles 511 as shown in FIG. 16 and FIG. 17. The cavity 521 has a volume that is variable by vibrations of the elastic film 550 to be described below. The cavity 521 is formed to eject ink by the volume change.

The elastic plate 550 is disposed on the ink chamber substrate 520 on the opposite side of the nozzle plate 510, and a plurality of piezoelectric sections 540 are provided on the elastic film 550 on the opposite side of the ink chamber substrate 520. A communication hole 531 that penetrates the elastic film 550 in its thickness direction is formed in the elastic film 550 at a predetermined position, as shown in FIG. 17. Ink is supplied from an ink cartridge 631 to be described below to the reservoir 523 through the communication hole 531.

Each of the piezoelectric sections 540 is electrically connected to a piezoelectric element driving circuit to be described below, and is structured to operate (vibrate, deform) based on signals of the piezoelectric element driving circuit. In other words, each of the piezoelectric sections 540 functions as a vibration source (head actuator). The elastic film 550 vibrates (warps) by vibration (warping) of the piezoelectric section 540, and functions to instantaneously increase the inner pressure of the cavity 521.

The base substrate 560 is formed from, for example, any one of various resin materials, any one of metal materials, or the like. The ink chamber substrate 520 is affixed to and supported by the base substrate 560, as shown in FIG. 17.

The ink jet recording head 500 in accordance with the present embodiment is highly reliable, has excellent piezoelectric characteristics, and is capable of effectively jetting ink, because cracks are difficult to occur in the piezoelectric sections 540. Accordingly, the nozzles 511 can be arranged with higher density, and higher resolution and faster printing become possible. Moreover, the overall size of the head can be made smaller.

### 6. Ink Jet Printer

Next, an ink jet printer equipped with the aforementioned ink jet recording head 500 is described. FIG. 18 is a schematic perspective view of an ink jet printer 600 in accordance with an embodiment of the invention, in which the ink jet printer is applied to an ordinary printer for printing on paper or the like. It is noted that the upper side in FIG. 18 is referred to as an “upper section,” and the lower side is referred to as a “lower section” in the following description.

The ink jet printer 600 is equipped with an apparatus main body 620, in which a tray 621 for holding recording paper P in an upper rear section thereof, a discharge port 622 for discharging the recording paper P to a lower front section thereof, and an operation panel 670 on an upper surface thereof are provided.

The apparatus main body 620 is provided on its inside, mainly, with a printing device 640 having a head unit 630 that can reciprocate, a paper feeding device 650 for feeding recording paper P one by one into the printing device 640, and a control section 660 for controlling the printing device 640 and the paper feeding device 650.

The printing device 640 is equipped with the head unit 630, a carriage motor 641 that is a driving source for the head unit 630, and a reciprocating mechanism 642 that receives rotations of the carriage motor 641 to reciprocate the head unit 630.

The head unit 630 includes the ink jet recording head 500 equipped with the aforementioned multiple nozzles 511 in its lower section, ink cartridges 631 that supply inks to the ink jet recording head 500, and a carriage 632 on which the ink jet recording head 500 and the ink cartridges 631 are mounted.

The reciprocating mechanism 642 includes a carriage guide shaft 643 having both ends thereof supported by a frame (not shown), and a timing belt 644 that extends in parallel with the carriage guide shaft 643. The carriage 632 is freely reciprocally supported by the carriage guide shaft 643, and affixed to a portion of the timing belt 644. By operations of the carriage motor 641, the timing belt 644 is moved in a positive or reverse direction through pulleys, and the head unit 630 reciprocally moves, guided by the carriage guide shaft 643. During these reciprocal movements, the ink is jetted from the ink jet recording heads 500, to print on the recording paper P.

The paper feeding device 650 includes a paper feeding motor 651 as its driving source and a paper feeding roller 652 that is rotated by operations of the paper feeding motor 651. The paper feeding roller 652 is formed from a follower roller 652a and a driving roller 652b that are disposed up and down and opposite each other with a feeding path of the recording paper P (i.e., the recording paper P) being interposed between the two, and the driving roller 652b is coupled to the paper feeding motor 651.

The ink jet printer 600 in accordance with the present embodiment is equipped with the ink jet recording head 500 that is highly reliable and has high performance in which the nozzles can be arranged in high density, which makes high resolution printing and high speed printing possible.

It is noted that the ink jet printer 600 in accordance with the present invention can also be used as a droplet discharge device that is used for industrial purposes. In this case, as ink (liquid material) to be jetted, a variety of functional materials may be used with their viscosity being appropriately adjusted by solvent, dispersion medium or the like.

7. The embodiments of the invention are described above in detail. However, those skilled in the art should readily understand that many modifications can be made without departing in substance from the novel matter and effects of the invention. Accordingly, all of such modified examples are deemed included in the scope of the invention.

Also, the piezoelectric element in accordance with the embodiment of the invention described above is applicable not only to actuators, ink jet recording heads and ink jet printers, but also to, for example, gyro devices of gyro sensors, FBAR (film bulk acoustic resonator) type or SMR (solid mounted resonator) type BAW (bulk acoustic wave) filters, ultrasound motors and the like. The piezoelectric element in accordance with the embodiment of the invention excels in piezoelectric characteristics and is highly reliable as described above, such that it is favorably applicable in many different usages.

What is claimed is:

1. A piezoelectric element comprising:
a first electrode formed above a base substrate;
a piezoelectric layer formed above the first electrode; and
a second electrode formed above the piezoelectric layer,
wherein the piezoelectric layer has a plurality of voids.

2. A piezoelectric element according to claim 1, wherein each of the voids is 100 nm or smaller in diameter.

3. A piezoelectric element according to claim 1, wherein the voids are arranged in a matrix in a plane parallel with a top surface of the base substrate.

4. A piezoelectric element according to claim 3, wherein the plurality of voids arranged in a matrix are provided in a plurality of layers.

5. A piezoelectric element according to claim 1, wherein the voids are formed in a greater number per unit volume as the voids are present closer to the first electrode.

6. A piezoelectric element according to claim 1, wherein the piezoelectric layer has a first piezoelectric layer having a plurality of voids, and a second piezoelectric layer that is formed above the first piezoelectric layer and does not have voids.

7. A piezoelectric element according to claim 1, wherein the piezoelectric layer includes lead zirconate titanate.

8. An ink jet recording head comprising the piezoelectric element recited in claim 1.

9. An ink jet printer comprising the ink jet recording head recited in claim 8.
